(19) United States
(12) Patent Application Publication
(10) Pub. No.: US 2022/0259730 A1
(43) Pub. Date: Aug. 18, 2022

(54) METHOD

(71) Applicant: UNIVERSITETET I OSLO, Oslo (NO)

(72) Inventors: Henrik Hovde SØNSTEBY, Nittedal (NO); Erik SKAAR, Fyllingsdalen (NO); Jon BRATVOLD, Oslo (NO); Ola NILSEN, Oslo (NO); Helmer FJELLVÅG, Oslo (NO)

(21) Appl. No.: 17/628,252

(22) PCT Filed: Jul. 17, 2020
(86) PCT No.: PCT/GB2020/051724

§ 371 Date: Jan. 19, 2022

(30) Foreign Application Priority Data
Jul. 19, 2019 (GB) 1910404.1

(51) Int. Cl. C23C 16/455; C23C 16/40; C23C 16/448; C30B 25/16; C30B 29/22

(52) U.S. Cl. CPC C23C 16/45531; C23C 16/406; C23C 16/45553; C30B 29/22; C23C 16/4485; C30B 25/165; C23C 16/45555

(57) ABSTRACT

The invention relates to methods for the formation of rare earth nickelate thin films and “doped” (i.e. cation-substituted) variants thereof on a substrate using atomic layer deposition (ALD). The films can be deposited at low temperature (e.g. at temperatures as low as 225° C.) and have a range of useful properties including good crystallinity and high electrical conductivity, as well as interesting magnetic, optic and catalytic properties. These properties make the materials suitable for use in microelectronic applications, in the production of electrodes and as catalytic surfaces.

The present invention relates to a method for the formation of rare earth nickelate thin films and “doped” (i.e. cation-substituted) variants thereof on a substrate. In particular, it relates to a method for the low temperature deposition of such thin films having a range of useful properties such as, but not limited to, good crystallinity and high electrical conductivity, as well as interesting magnetic, optic and catalytic properties.

In recent years, there has been an increasing interest in methods of forming thin material films on substrates of various kinds for use in applications such as electronics and energy storage. The rare earth nickelates are a group of materials with highly attractive properties, such as high electrical conductivity, which makes them particularly suitable for use in a range of applications such as electrode materials in supercapacitors, in battery anodes, and in functional heterostructures. They may, for example, replace platinum in device integration of piezo and ferroelectrics in SAW-devices, ferroelectric RAM and transducers. When oriented directly on silicon, they may also play a crucial role in resistance switching in consumer electronics. LaNiO₃ has one of the lowest electrical resistivities found in perovskite complex oxides. It is the best electrical conductor out of the rare earth nickelates (having the highest conductivity and no metal to insulator transition (MIT)). The other members of the rare earth nickelates also exhibit interesting properties and may, for example, undergo electronic transitions. For example, PrNiO₃ and NdNiO₃ still behave like metals under ambient conditions, whereas SmNiO₃ exhibits an MIT just above room temperature. These therefore also have a range of potential applications, such as in optoelectronics (SmNiO₃ and NdNiO₃), ion conduction (SmNiO₃), and in Mott transistors (NdNiO₃).

Current methods for the deposition of rare earth nickelates, such as molecular beam epitaxy (MBE) and pulsed laser deposition (PLD), require elevated temperatures which makes them unsuitable for monolithic device integration. These methods also have limitations in terms of the size of the substrate which can be coated, and are not suitable for coating of non-flat substrates. Alternative methods of forming thin films of rare earth nickelates are therefore required to unlock the potential of these materials in electronic applications.

Atomic layer deposition or “ALD” (also known as atomic layer chemical vapour deposition, ALCVD, or atomic layer epitaxy, ALE) is a thin-film-deposition technique that relies on alternating self-terminating gas-to-surface reactions. In typical ALD processes, the film is formed by sequential pulsing of two or more reactants (otherwise generally referred to as “precursors”), using purging with inert gas between the precursor pulses to avoid gas-phase reactions. Unlike most other deposition and crystal growth techniques, this method ensures an even growth of the film on all exposed surfaces. To date, however, ALD has not found widespread use in the deposition of complex metal oxide materials.

In ALD processes, the stoichiometry of the deposited films may be varied by altering the ratio of the different precursor pulses. As different precursors have different properties, atomic arrangements and effective molecular sizes, they do not contribute equally to the growth of the deposited film. Once the desired precursor ratio is established, it is common practice in ALD to follow the principle of “maximum mixing” when selecting the particular sequence of pulses. This facilitates chemical uniformity in the deposited films. For example, if a 7:2 pulse ratio of two different precursors is necessary to provide the desired stoichiometry in the deposited film, the conventional practice would be to deploy a “maximally mixed” 4:1:3:1 pulse sequence—i.e. to employ a deposition cycle in which 4 sequential pulses of the first precursor are followed by a single pulse of the second precursor, followed by 3 sequential pulses of the first precursor and, finally, a single pulse of the second precursor. This is the approach previously adopted when using ALD to deposit a thin film of LaNiO₃ on Si and SrTiO₃ substrates using La(thd)₃, Ni(acac)₂ and 03 as precursors (see Hauge-Iversen, Jon Magnus. Syntese og karakterisering av tynne filmer av lantan nikkeloksid. Master thesis, University of Oslo, 2014, available at: https://www.duo.uio.no/handle/10852/42298). Although this ALD process provided a crystalline film on SrTiO₃, only amorphous layers were deposited on Si, and an annealing step at 800° C. in oxygen was required to obtain crystalline layers.

The inventors have now recognised that the pulsing sequence used in ALD directly impacts the structure and functional properties of the “as deposited” film.

Specifically, they have found that the adoption of highly unusual pulsing sequences improves the deposition method, allowing highly crystalline and thus highly conductive films of relevant rare earth nickelates (and “doped” variants) to be deposited at low temperature (e.g. at temperatures as low as 225° C.) on a range of substrates without the need for any high temperature post-annealing step. They have also surprisingly found that thermal treatment of the nickel precursor (Ni(acac)₂) prior to its use in the ALD process impacts the properties of the deposited material.

Viewed from one aspect the invention provides a method for the formation of a rare earth nickelate-containing film, or a doped variant thereof, on a substrate by atomic layer deposition, said method comprising the following steps:
a) providing a substrate in a reaction chamber wherein said reaction chamber is arranged for gas-to-surface reactions;
b) depositing a rare earth nickelate, or doped variant thereof, on at least a portion of said substrate by means of a deposition cycle which comprises sequential pulsing of a rare earth precursor, an oxygen precursor, a nickel precursor and, optionally, one or more dopant precursors, through said reaction chamber whereby to cause each precursor to deposit on and/or react with at least one surface of said substrate; and
c) repeating step b), if desired, until the required film thickness is obtained;
   wherein the deposition cycle in step b) comprises the following steps i) and ii) carried out sequentially:
i) sequential pulsing of said rare earth precursor and said oxygen precursor, repeated “A” times;
ii) sequential pulsing of said nickel precursor and said oxygen precursor, repeated “B” times, in which at least one pulse of said nickel precursor is optionally substituted by a pulse of a dopant precursor;
   wherein:

### A is 5 or 10;

### B is 2 or 4; and

the ratio of A:B is 2.5:1;
and further wherein the nickel precursor is [Ni(acac)₂]₃.

“Atomic layer deposition” or “ALD”, as referred to herein, means a process in which deposition of material onto the surface of a substrate is achieved by sequential and alternating self-saturating surface reactions. Alternating pulses of precursors are provided to the reaction chamber. Each pulse saturates the surface in a self-limiting manner. The layer left by a pulse is self-terminated with a surface that is non-reactive with the remaining chemistry of that pulse. Each subsequent pulse reacts with the surface left by the preceding pulse in a similarly self-limiting or self-terminating manner such that each deposition cycle of pulses leaves no more than about one monolayer of the deposited material.

In the method of the invention, step b) may be considered a “deposition cycle” and is repeated until the desired film thickness is achieved. This “deposition cycle” comprises a first step of sequentially pulsing the rare earth precursor and the oxygen precursor, repeated “A” times (i.e. step i)). It further comprises a second step of sequentially pulsing the nickel precursor and the oxygen precursor, repeated “B” times (i.e. step ii)). Where a doped variant is to be produced, one or more pulses of the nickel precursor in step ii) may be substituted (i.e. replaced) by one or more pulses of a suitable dopant precursor. More than one type of dopant precursor may be used. As will be understood, a single pulse of a dopant precursor will be used in place of a single pulse of the nickel precursor thereby retaining the desired overall pulse sequence. Steps i) and ii) are carried out sequentially. The “deposition cycle” may be repeated, as required, to produce the desired film of rare earth nickelate material (or doped variant thereof) on the substrate.

In certain embodiments, each “deposition cycle” in the method of the invention may be represented by way of the following formula:

[{RE+O}×A+{Ni+O}×B]

in which:
“RE” denotes the step of pulsing the rare earth precursor;
“Ni” denotes the step of pulsing the nickel precursor;
“O” denotes the step of pulsing the oxygen precursor;
“A” denotes the number of times the rare earth precursor and oxygen precursor are repeatedly pulsed; and
“B” denotes the number of times the nickel precursor and oxygen precursor are repeatedly pulsed;
wherein:

### A is 5 or 10;

### B is 2 or 4; and

the ratio of A:B is 2.5:1.

The deposition cycle in step b) may be repeated as required to achieve the desired film thickness. For example, it may be repeated from 1 to 1000 times, preferably 50 to 300 times, more preferably 100 to 200 times, or 130 to 160 times, e.g. about 140 to 150 times. In one embodiment, 143 deposition cycles may be performed. Preferably the method is carried out whereby to produce a continuous layer having a thickness of at least 20 nm, preferably at least 25 nm. Films having a thickness of up to about 200 nm may, for example, be produced depending on the number of cycles performed. Very thin films, for example those having a thickness of less than about 10 nm, e.g. less than about 5 nm, may be deposited using a fewer number of cycles. For example, these may be produced by repeating the deposition cycle from 5 to 20 times, e.g. from 8 to 17 times. Thin films having a thickness of less than 5 nm, e.g. from 2 to 4 nm, may be produced.

The growth per cycle of the process is typically about 0.2 Å to 0.6 Å, preferably about 0.28 Å to 0.35 Å, e.g. about 0.3 Å, depending on the nature of the substrate. Films of different thicknesses can be deposited by varying the number of cycles, preferably to obtain films of a thickness of from about 0.38 nm (e.g. the thickness of one unit cell) to about 60 nm, preferably from about 1.5 to about 40 nm.

As would be understood in the context of a typical ALD process, the pulse sequence will include purging of the reaction chamber between pulses to help remove unreacted precursor molecules and any possible by-products. Typically it will include a series of purge pulses. For example, an inert purge gas may be pulsed through the reaction chamber after each pulse of rare earth precursor, or after each sequence of rare earth precursor pulses, or even concurrently with the rare earth precursor. Alternatively, several purge pulses may be performed between each rare earth precursor pulse. Similarly, purging steps may also be performed after pulsing of the oxygen precursor, after pulsing of the nickel precursor, and after pulsing of any dopant precursor (if used). The purging steps are intended to remove any unreacted reactants thereby ensuring that growth of the firm proceeds according to self-limiting gas-to-surface reactions. Alternatively, unreacted precursor molecules and any by-products may be removed from the reaction chamber simply by varying the pressure in the reaction chamber, e.g. by evacuation of the chamber.

Purging of the reaction chamber may be performed by flowing a purge gas through the chamber or, alternatively, by evacuating the chamber by reducing the pressure. Suitable purge gases include inert gases such as nitrogen, argon, etc., although any suitable gas or gas mixture may be used which will not react with the deposited film or the precursors. Preferred for use as a purge gas in the method of the invention is nitrogen.

The inventors have found that the pulse sequence is particularly important in depositing a rare earth nickelate (or suitably doped variant thereof) having desirable properties, in particular good crystallinity and high electrical conductivity (i.e. low resistivity).

In one embodiment of the method, the deposition cycle in step b) involves a pulse sequence comprising 5 pulses of the rare earth precursor followed by 2 pulses of the nickel precursor. This deposition cycle can be represented as:

[{RE+O}×5+{Ni+O}×2]

This should be understood as follows:
one pulse of rare earth precursor, one pulse of oxygen precursor, repeated 5 times;
one pulse of nickel precursor, one pulse of oxygen precursor, repeated 2 times.

More specifically, where each precursor pulse is followed by purging of the reaction chamber, one deposition cycle will comprise:
one pulse of rare earth precursor, one purge, one pulse of oxygen precursor, one purge, repeated 5 times;
one pulse of nickel precursor, one purge, one pulse of oxygen precursor, one purge, repeated 2 times.

In another embodiment of the method, the deposition cycle in step b) involves a pulse sequence comprising 10 pulses of the rare earth precursor followed by 4 pulses of the nickel precursor. This deposition cycle can be represented as:

[{RE+O}×10+{Ni+O}×4]

This should be understood as follows:
one pulse of rare earth precursor, one pulse of oxygen precursor, repeated 10 times;
one pulse of nickel precursor, one pulse of oxygen precursor, repeated 4 times.

More specifically, where each precursor pulse is followed by purging of the reaction chamber, one deposition cycle will comprise:
one pulse of rare earth precursor, one purge, one pulse of oxygen precursor, one purge, repeated 10 times;
one pulse of nickel precursor, one purge, one pulse of oxygen precursor, one purge, repeated 4 times.

The methods herein described provide “as deposited” rare earth nickelate films having particularly desirable structural and functional properties. In this context, “as deposited” is intended to refer to a film prepared by deposition on a substrate but which has not been subjected to any post-deposition treatment, such as for example annealing.

ALD typically results in films that are amorphous and which must be subjected to a high temperature annealing step to achieve the desired level of crystallinity. However, the inventors have surprisingly found that the methods of the present invention enable highly crystalline films to be deposited directly at low temperatures and on a range of different substrates. In certain embodiments, the deposited films exhibit electrical conductivity that surpasses that of any complex metal oxide film deposited at low temperatures, and the resistivity of these films is comparable to bulk values for films deposited at temperatures as low as 225° C. If required, the electrical conductivity of the materials can be further improved by post-deposition annealing which can improve the macroscopic crystallinity of the films and convert them to a lower resistivity phase. However, there is no requirement for any post-deposition treatment unless any given application specifically requires as high a conductivity as possible. In certain embodiments of the invention, an annealing step may be carried out following deposition of the thin film. In other embodiments, however, no annealing step is performed.

It is particularly unexpected that the methods herein described enable conductive films to be obtained “as deposited” on untreated silicon substrates, i.e. without the requirement for any particular pre-treatment of the substrate. This is significant because oriented complex metal oxides on silicon are otherwise hard to obtain. Given the widespread use of silicon in electronic devices, this opens up a range of new applications for rare earth nickelate thin films formed by ALD, for example as an enabling technology for integration of novel oxide based electronics. Since the methods of the invention can be carried out at low temperatures, they are also compatible with monolithic device integration.

The rare earth precursor for use in the method of the invention may comprise any of the rare earth elements, or any combination of such elements. In one embodiment, it may comprise La, Pr, Nd, Sm, Eu, Gd, Tb, Dy, Ho, Er, Tm, Yb, or Lu, or any combination thereof. In one embodiment, it may comprise La, Pr, Nd, or Sm, preferably La. The use of a mixed rare earth precursor which contains more than one rare earth metal (e.g. two rare earth metals) may be effective to tune the electrical properties of the films. For example, La may be used in combination with at least one (e.g. one) other rare earth element.

The rare earth precursor may be used in the form of a complex comprising one or more ligands which may be selected from 2,2,6,6-tetramethyl-3,5-heptane-dione (thd), cyclopentadienyl (Cp), ethyl cyclopentadienyl (CpEt), isopropyl cyclopentadienyl (CpⁱPr), isopropyl amidinate (ⁱPrAMD), and isopropyl formamidate (ⁱPrFMD). The rare earth precursor may, for example, be selected from RE(Cp)₃, RE(CpEt)₃, RE(CpⁱPr)₃, RE(ⁱPrAMD)₃, and RE(ⁱPrFMD)₃, wherein RE=a rare earth element such as La, Pr, Nd, Sm, Eu, Gd, Tb, Dy, Ho, Er, Tm, Yb or Lu.

The rare earth precursor may, for example, be selected from La(thd)₃, Pr(thd)₃, Nd(thd)₃, Sm(thd)₃, Eu(thd)₃, Gd(thd)₃, Tb(thd)₃, Dy(thd)₃, Ho(thd)₃, Er(thd)₃, Tm(thd)₃, Yb(thd)₃, and Lu(thd)₃. In one embodiment, the rare earth precursor is La(thd)₃.

Any suitable oxygen precursor may be used, such as for example, water, O₃ or any other oxygen comprising gaseous compound. Combinations of oxygen precursors may also be used, either in separate pulsing steps or simultaneously in the same pulsing step.

The nickel precursor for use in the method of the invention is [Ni(acac)₂]₃. This can be formed by sublimation of Ni(acac)₂ before introduction of the nickel precursor to the reaction chamber. Ni(acac)₂ may, for example, be sublimated in a cold finger sublimation procedure. This may be performed at a temperature in the range of from 160 to 200° C., preferably 175 to 180° C. The duration of the sublimation process may be up to about 48 hours, preferably about 24 hours. The sublimation step serves the dual purpose of purifying the Ni(acac)₂ and simultaneously forming the nickel triad, [Ni(acac)₂]₃.

The inventors have recognised that the nickel triad, [Ni(acac)₂]₃, plays an important role in enabling the deposition of highly crystalline rare earth nickelate films (and doped variants thereof) at low temperature. When using Ni(acac)₂ in the work documented in the earlier Master thesis (2014), this material was available only in relatively impure form and hence subjected to sublimation merely for purification purposes. Neither the formation of [Ni(acac)₂]₃ on sublimation, nor its importance in the deposition of highly crystalline films, was recognised. Without wishing to be bound by theory, it is thought that, in the case of LaNiO₃, because the Ni—O—Ni bond distances are similar in [Ni(acac)₂]₃ and LaNiO₃, formation of an epitaxial film is facilitated. Similar considerations extend to the other rare earth elements. The use of [Ni(acac)₂]₃ as a nickel precursor in the deposition of rare earth nickelate films, and in doped variants of such films, therefore represents a broader aspect of the invention.

Viewed from a further aspect the invention thus provides a method for the formation of a rare earth nickelate-containing film, or a doped variant thereof, on a substrate by atomic layer deposition, said method comprising the following steps:
a) providing a substrate in a reaction chamber wherein said reaction chamber is arranged for gas-to-surface reactions;
b) depositing a rare earth nickelate, or doped variant thereof, on at least a portion of said substrate by means of a deposition cycle which comprises sequential pulsing of a rare earth precursor, an oxygen precursor, a nickel precursor and, optionally, one or more dopant precursors, through said reaction chamber whereby to cause each precursor to deposit on and/or react with at least one surface of said substrate; and
c) repeating step b), if desired, until the required film thickness is obtained;
   wherein the nickel precursor is [Ni(acac)₂]₃; and
   wherein the rare earth precursor is other than La(thd)₃.

In one embodiment of this aspect of the invention, the rare earth precursor does not contain lanthanum. For example, it may comprise any of the other rare earth elements, such as any of those herein described. Specifically, the rare earth precursor may comprise Pr, Nd, Sm, Eu, Gd, Tb, Dy, Ho, Er, Tm, Yb, or Lu, or any combination thereof. In one embodiment, the rare earth precursor may contain lanthanum in combination with a different rare earth element.

Viewed from a yet further aspect the invention provides a method for the formation of a doped rare earth nickelate-containing film on a substrate by atomic layer deposition, said method comprising the following steps:
a) providing a substrate in a reaction chamber wherein said reaction chamber is arranged for gas-to-surface reactions;
b) depositing a doped rare earth nickelate on at least a portion of said substrate by means of a deposition cycle which comprises sequential pulsing of a rare earth precursor, an oxygen precursor, a nickel precursor, and one or more dopant precursors, through said reaction chamber whereby to cause each precursor to deposit on and/or react with at least one surface of said substrate; and
c) repeating step b), if desired, until the required film thickness is obtained;
   wherein the nickel precursor is [Ni(acac)₂]₃.

In any of the embodiments of the invention, the term “dopant precursor” is intended to refer to a material which is capable of producing the desired dopant metal during the ALD process. As will be understood, the dopant precursor will comprise a metal other than nickel. Typically, it will comprise a transition metal element such as described below.

Doped films can be obtained using any of the methods herein described. Doping may be desirable, for example, to tune the resistivity of the rare earth nickelate-containing film. The terms “doping” or “doped” are used herein to refer to the substitution of a proportion of nickel cations in the rare earth nickelate with one or more other metal cations. For example, at least 1 mol. %, at least 2 mol. %, at least 3 mol. %, at least 4 mol. % or at least 5 mol. % of the nickel cations can be replaced with other metal cations. Alternatively, up to 90 mol. % of the nickel cations can be replaced with other metal cations, preferably up to 80 mol. %, up to 70 mol. %, up to 60 mol. %, up to 50 mol. %, up to 40 mol. %, up to 30 mol. %, up to 20 mol. % or up to 10 mol. %. These upper and lower limits can be combined in any way.

Suitably “doped” films can be obtained by exchanging one or more pulses of the nickel precursor with one or more pulses of a precursor to the desired dopant (herein referred to as a “dopant precursor”). Suitable dopants may include, but are not limited to, transition metals and combinations of transition metals, such as Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, or Hg. Preferred dopants include Co, Cu, Fe, Zn, Mn, and Sc, preferably Co, Cu and Fe, for example Cu.

For example, copper-doped rare earth nickelates can be obtained by exchanging one or more pulses of the nickel precursor with a pulse (or pulses) of a suitable copper precursor. The copper precursor may, for example, be Cu(acac)₂.

In any of the methods herein described, any gaseous precursors may be introduced from a compartment which is separated from the reaction chamber, for example via a physical or inert gas valve. Such gaseous precursors may enter the reaction chamber by way of their own intrinsic vapour pressure or optionally by means of an inert carrier gas.

Any precursors which exist in solid (e.g. powdered) or liquid form, such as the rare earth metal precursors, may be converted to the gaseous state by “direct vaporisation” prior to introduction into the reaction chamber. By “direct vaporisation” is meant that a substantially pure (e.g. pure) precursor compound in solid or liquid form is converted directly to the gaseous state via sublimation or evaporation without dispersion or dissolution in a liquid (e.g. a solvent or emulsion). Optionally, an inert gas may be employed (e.g. via a bubbler) to assist in the vaporisation and/or act as a carrier gas. Alternatively, vaporisation of solid or liquid precursors may be carried out in situ in the reaction chamber. Vaporisation of any precursors should be carried out at an evaporation temperature capable of giving rise to a sufficient amount of precursor for use in the ALD process. Appropriate vaporisation temperatures will depend on the nature of the precursor and the ALD process conditions and may readily be determined by those skilled in the art. Such temperatures are typically from about 100 to 200° C. For example, for deposition of LaNiO₃, the lanthanum and nickel precursors may be held in the reaction chamber at a temperature of about 160 to 200° C., e.g. about 185° C.

It will be understood that the term “substrate” as used herein refers to any surface on which the rare earth nickelate film, or doped variant thereof, is to be deposited. Suitable substrate materials include any materials which are capable of withstanding the reaction conditions within the reaction chamber. Examples of substrate materials include semiconductor structures, for example Si (e.g. single crystalline Si(111)), SiO₂, Si/SiO₂ (such as Si (100) with native SiO₂); metallic surfaces, for example Si/Pt, Pt, or Ti; crystalline ceramics, for example SiO₂ and Al₂O₃; amorphous glasses, for example glass; or other materials such as LaAlO₃ (such as LaAlO₃ (100), available from e.g. Crystal GmbH), MgO, SrLaAlO₄, SrTiO₃ (such as SrTiO₃ (100), available from e.g. Crystal GmbH, SrTiO₃ (110) or SrTiO₃ (111)), KNbO₃, K(Nb,Ta)O₃, NdGaO₃, TbScO₃, and YAlO₃.

Where required, a substrate surface may be pre-treated prior to deposition of the desired film. For example, a silicon substrate may be etched using a solution containing HF.

The term “deposition temperature” refers to the temperature of the substrate during the deposition process. Deposition temperatures may be varied depending on the nature of the precursor materials used, the nature of the substrate, and the desired deposition rate. For example, the deposition temperature may be adjusted to ensure that deposition occurs at an optimum rate. As would be readily understood, the temperature must not be too high that the substrate is damaged or that the precursor is decomposed to any appreciable extent. Suitable deposition temperatures may readily be determined by those skilled in the art based on the chosen precursor materials. In a preferred embodiment, the methods herein described may be performed at low deposition temperatures, for example at a deposition temperature of less than about 300° C., e.g. less than about 250° C. A temperature in the range of about 210 to 230° C., e.g. a temperature of about 225° C., is preferred.

Pulse durations may be varied according to need, however, the pulse duration of each precursor will be such that there is sufficient time for a substantial proportion of the substrate surface (e.g. the entire substrate surface) to react with the precursor. Pulse durations can readily be determined by those skilled in the art. Since the pulses are self-limiting there is, strictly speaking, no upper limit on the pulse duration.

Typical precursor pulse durations will be at least 0.1 seconds, preferably from about 0.1 to about 20 seconds, more preferably from about 1 to about 5 seconds. When pulsing the rare earth precursor, this will generally have a pulse duration of about 1 to about 5 seconds, preferably of at least 2 seconds. When pulsing the oxygen precursor this will generally have a pulse duration of about 1 to about 5 seconds, preferably of at least 4 seconds. When pulsing the nickel precursor (or dopant precursor), this may have a pulse duration of about 1 to about 5 seconds, preferably of at least 2 seconds.

Similarly, the purge pulse durations may be tailored to ensure that the purge is effective; typical purge pulse durations may range from about 0.1 to 12 seconds, preferably about 0.8 to about 5 seconds, e.g. about 1 to 2 seconds.

The products, i.e. the film-coated substrates, produced by any of the methods herein described have valuable properties, for example in terms of their electrical (resistivity and conductivity) properties and/or their degree of crystallinity, and these products form a further aspect of the invention. Such products will comprise a substrate carrying a rare earth nickelate film, or doped variant thereof. The films produced may have a layered structure or may comprise a monolayer.

Viewed from a further aspect, the invention thus provides a substrate carrying a rare earth nickelate-containing film, or doped variant thereof, obtained or obtainable by any method as described herein.

As noted above, as a result of the deposition methods herein described the thin films have good electrical conductivity. Such films may, for example have a resistivity in the range of 1×10⁻⁵ to 100 Ωcm, preferably 3×10⁻⁴ to 100 Ωcm, e.g. 3×10⁻⁴ to 2×10⁻³ Ωcm. By the term “resistivity” as used herein is meant in particular sheet resistance, i.e. resistance in the plane of the thin film. Sheet resistance is related to the resistance, R, and the resistivity, ρ, by the following expressions:

$$R = ρ \frac{L}{A} = ρ \frac{L}{Wt}$$

where ρ is the resistivity, A is the cross-sectional area and L is the length. The cross-sectional area can be split into the width Wand the sheet thickness t. Upon combining the resistivity with the thickness, the resistance can then be written as:

$$R = \frac{ρ}{t} \frac{L}{W} = {R}_{s} \frac{L}{W}$$

where Rₛ is then the sheet resistance.

In another aspect the invention thus provides a substrate carrying a rare earth nickelate-containing film, or doped variant thereof, deposited by ALD, wherein said film has a resistivity in the range of 1×10⁻⁵ to 100 Ωcm, preferably 3×10⁻⁴ to 100 Ωcm, e.g. 3×10⁻⁴ to 2×10⁻³ Ωcm. A substrate carrying an “as deposited” film having such characteristics represent a preferred embodiment of the invention.

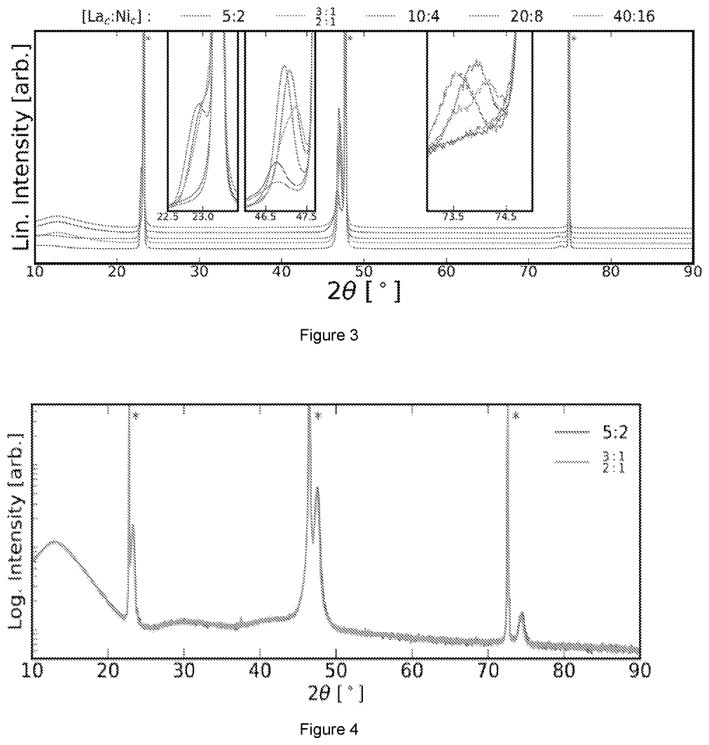

The rare earth nickelate materials, or doped variants thereof, which are deposited on the substrate surface also form a further aspect of the invention. Those produced according to the examples provided herein are particularly preferred materials and may be characterised by one of more of the following: (i) an X-ray diffraction pattern according to that labelled 5:2 in FIG. 2; (ii) an X-ray diffraction pattern according to that labelled 10:4 in FIG. 2; (iii) an X-ray diffraction pattern according to that labelled 5:2 in FIG. 3; or (iv) an X-ray diffraction pattern according to that labelled 10:4 in FIG. 3.

The thin films formed by the methods herein described find a variety of uses, including in particular, use in microelectronic applications such as in the production of a battery, a supercapacitor, a surface acoustic wave device, a ferroelectric random-access memory, a transducer, an ion conductor, an optoelectronic device, a Mott transistor, an actuator, a sensor, or a magnetoelectric device. They also find use in the production of electrodes, and as catalytic surfaces.

The invention is illustrated further in the following non-limiting Examples and in the attached Figures, in which:

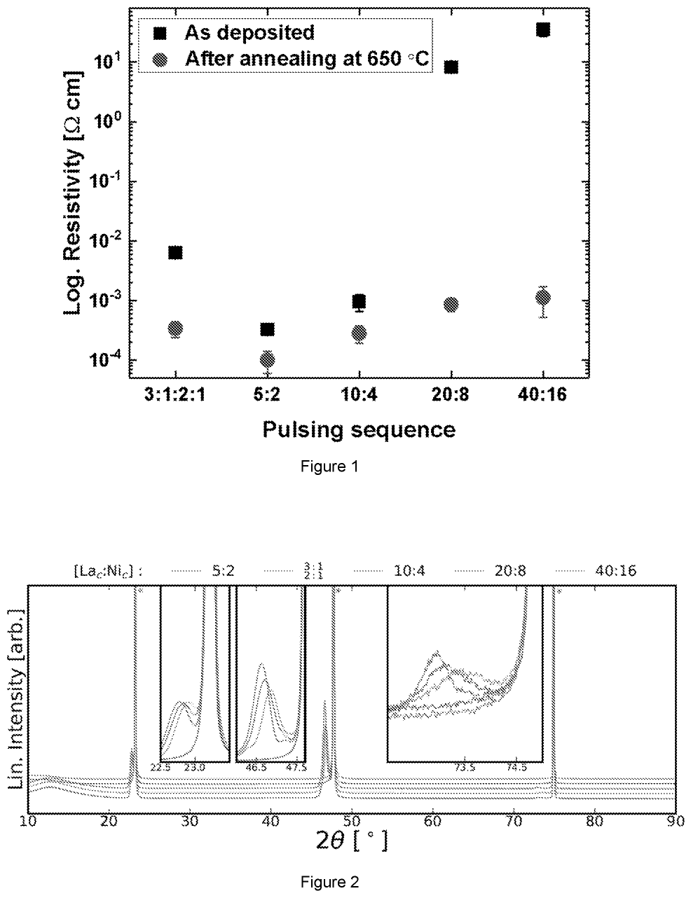

FIG. 1: Electrical resistivity of thin films of LaNiO₃ deposited on LaAlO₃ as a function of the pulsing ratio. 3:1:2:1 denotes a repeated pulsing sequence of La:La:La:Ni:La:La:Ni, whereas 5:2 denotes La:La:La:La:La:Ni:Ni, and so on. Squares denote as deposited films, whereas circles denote post-annealed films.

FIG. 2: X-ray diffractograms of as deposited LaNiO₃ thin films, deposited with 5 different pulsing sequences.

FIG. 3: X-ray diffractograms of post annealed LaNiO₃ thin films, deposited with 5 different pulsing sequences.

FIG. 4: X-ray diffractogram of LaNiO₃ on SrTiO₃ as deposited at 225° C. The material is highly oriented and phase pure.

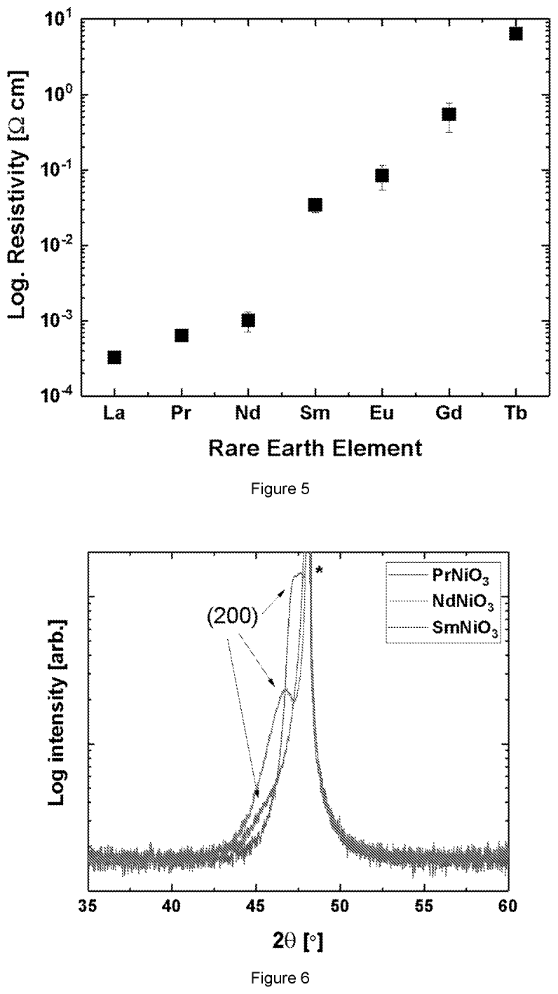

FIG. 5: Electrical resistivities of RENiO₃ thin films under ambient conditions (i.e. at room temperature), with RE-element shown on x-axis. All resistivities are from films as deposited at 225° C., with no post-treatment. For comparison, an uncoated substrate exhibits a resistivity in the 10⁵ Ωcm range.

FIG. 6: X-ray diffractograms of RENiO₃ (RE=Pr, Nd, Sm), showing the (200)-reflection of oriented thin films as-deposited at 225° C. The decreasing crystallinity is believed to be attributed to a slight alteration of the optimal pulsing ratio between RE and Ni.

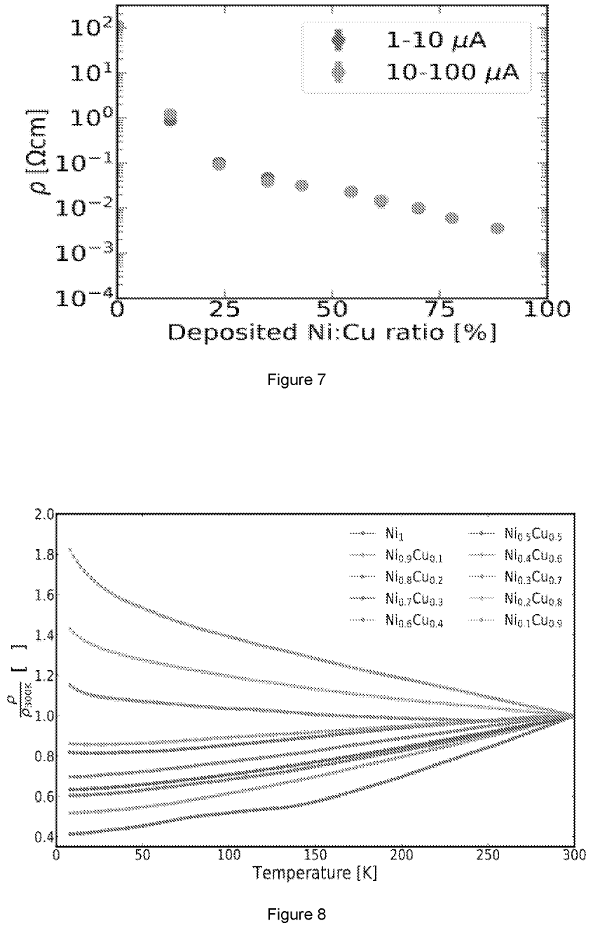

FIG. 7: Resistivity as a function of Ni:Cu-ratio in the LaNi₁₋ₓCuₓO₃-system.

FIG. 8: Resistivity as a function of temperature for the different samples in the copper-substituted (i.e. doped) series.

### EXAMPLES

General Procedure: ALD of RE(Ni,Cu)O₃ where “RE”=Rare Earth Element

Depositions of LaNiO₃ were carried out using an F-120 Sat ALD reactor (ASM Microchemistry) with La(thd)₃ (thd=2,2,6,6-tetramethyl-3,5-heptadionate), Ni(acac)₂ (acac=acetyl acetonate) and O₃ as precursors. O₃ was supplied externally by an AC-2505 ozone generator, yielding 15 mass % O₃ in O₂, and fed to the ALD reactor in inert tubes. For copper substituted (i.e. doped) variants, a fraction of Ni(acac)₂ pulses were exchanged by Cu(acac)₂ pulses. For other RENiO₃ systems, La(thd)₃ was exchanged with the appropriate RE(thd)₃ compound. The metal precursors were used in powder form and were held in open boats internally in the reactor for the duration of deposition. The reactor system was constructed with eight separate heat zones in which precursors could be supplied from four.

For the deposition of LaNiO₃, La(thd)₃ and Ni(acac)₂ were held at 185° C. throughout the deposition, ensuring sufficient vapour pressure for surface saturation during growth. Metal precursors were pulsed into the chamber by internal inert gas valves, while 03 was pulsed by an external pneumatic valve. The reactor was maintained at 2.6 mbar throughout the deposition with a primary and secondary N₂-flow of 300 sccm and 200 sccm, respectively, used as purging gas. The temperature in the reaction chamber was maintained at 225° C. throughout deposition.

For copper substitution, Cu(acac)₂ was held at 140° C. throughout the deposition.

Ni(acac)₂ was resublimated before use as a precursor. This was carried out in vacuo at 175° C. with a cold finger at which the precursor was back-deposited upon sublimation. This changed the colour of the precursor from light green to dark emerald green, ensuring a transformation from Ni(acac)₂(H₂O)₂ to [Ni(acac)₂]₃. We have found that this transformation, which has been confirmed by X-ray diffraction, is required for the epitaxial growth of the films. Without wishing to be bound by any theory, it is this thought that the Ni—O—Ni bond distances in [Ni(acac)₂]₃ are similar to those in LaNiO₃, and that this aids in forming an epitaxial film as deposited.

Crystallinity and orientation were determined using a Bruker AXS D8 Discover diffractometer, with a Cu-Kai source and equipped with a LynxEye detector. Film thickness was determined by ellipsometry (J.A. Woolam α-SE) and X-ray reflectivity (PANalytical Empyrean). Resistivity at room temperatures was measured using a Jandel Cylindrical four point probe head connected to a Keithley 2400 Sourcemeter. Temperature dependent resistivity was measured in a Model 4000 Physical Property Measurement System (PPMS, Quantum Design), cooled with liquid helium.

### Example 1: Deposition of LaNiO₃ on LaAlO₃

LaNiO₃ was deposited by sequentially pulsing the precursors, allowing substrate surface saturation for every pulse. The deposition was carried out in cycles, where one deposition cycle may be represented as:

[{La(thd)₃+O₃}×A+{[Ni(acac)₂]₃+O₃}×B]×n

This should be interpreted as:
2 s pulse of La(thd)₃, 2 s purge, 4 s pulse of O₃, 2 s purge, repeated A times;
followed by:
2 s pulse of [Ni(acac)₂]₃, 2 s purge, 4 s pulse of O₃, 2 s purge, repeated B times.

This is one deposition cycle which may be repeated as many times (n) as needed to achieve the desired film thickness.

The growth per cycle of the process was ˜0.3 Å depending on the substrate, and so this is also the resolution for thickness control. Films were deposited ranging from 1.5 to 40 nm by varying n.

Thin films were deposited using the following pulse sequences: 5:2, 10:4, 20:8 and 40:16. To test the conventional principle of maximum mixing, a thin film was deposited using a pulsing sequence of 3:1:2:1, i.e. three pulses of La(thd)₃, followed by one pulse of [Ni(acac)₂]₃, then two pulses of La(thd)₃, then one pulse of [Ni(acac)₂]₃, each interspersed with pulses of O₃ and purging. All films were annealed at 650° C.

The resistivity and crystallinity of the thin films was studied before and after the annealing step. FIG. 1 shows the electrical resistivity, which correlates to conductivity, of the thin films before and after annealing. As can be seen, thin films deposited using the 5:2 and 10:4 pulsing sequences exhibit lower resistivity than that produced with the 3:1:2:1 pulse sequence. This resistivity was reduced further by annealing. Thin films deposited using the 20:8 and 40:16 pulse sequences had high resistivity as deposited. However, annealing reduced the resistivity of these films to levels similar to that of the annealed thin film deposited using the 3:1:2:1 pulse sequence.

The resistivity is closely related to crystallinity and orientation of the films. This can be seen from X-ray diffractograms for as deposited (FIG. 2) and post-annealed films (FIG. 3), respectively. Sharper reflections represent a greater degree of crystallinity. It is clear that the reflections for the thin films deposited using the 5:2 and 10:4 pulsing sequences show a greater degree of crystallinity both before and after annealing than those deposited using other pulse sequences.

The pulsing sequence (i.e. the order of pulsing the different precursors) was thus found to be of high importance in achieving the optimal crystallinity and electrical properties. This was most pronounced for the as deposited films, i.e. films that had not undergone any post annealing. A pulse ratio of 5 La(thd)₃: 2 [Ni(acac)₂]₃ in a given cycle was found to be optimal for the deposition of layers having a 1:1 ratio of lanthanum and nickel.

### Example 2: Deposition of LaNiO₃ on Other Substrates

LaNiO₃ thin films were deposited on other substrates using the same reaction conditions and pulsing sequences as in Example 1.

Highly crystalline thin films were obtained as deposited on silicon (HF-etched Si), LaAlO₃, SrTiO₃, MgO, Al₂O₃ and SrLaAlO₄ (FIG. 4 exemplifies SrTiO₃) and found to conduct electricity with resistivities ranging from 3×10⁻⁴ Ωcm to 2×10⁻³ Ωcm, depending on the substrate (lowest on LaAlO₃). This is comparable to bulk values of resistivity for LaNiO₃, reported at 1×10⁻⁴ Ωcm. After annealing at 650° C., the resistivity reduced to 8×10⁻⁵ Ωcm, which is lower than bulk values for resistivity in LaNiO₃. When silicon was used as the substrate, the LaNiO₃ film exhibited a resistivity of 2×10⁻³ Ωcm as deposited, which decreased to 5×10⁻⁴ Ωcm after annealing. The lowest resistivity reported so far for LaNiO₃ thin films by ALD is 5×10⁻⁴ Ωcm, but this is for films post-annealed at 700° C. The methods herein described are able to produce thin films that have a much higher conductivity than this without undergoing any high temperature post-annealing process.

### Example 3: Deposition of Other Rare Earth Nickelates—RENiO₃

A series of other rare earth nickelates were deposited using the same method as in the General Procedure, but replacing the La(thd)₃ precursor with the analogous rare earth element precursor. The films were deposited on LaAlO₃ using a pulsing sequence of 5:2.

The resistivities of the as deposited thin films obtained in this way were measured and are shown in FIG. 5. As can be seen, thin films containing La, Pr and Nd have low resistivities as deposited. The resistivity of thin films containing Sm, Eu, Gd and Tb was somewhat higher; this is as expected due to their intrinsic material properties. Crystallinity of as deposited films of PrNiO₃, NdNiO₃ and SmNiO₃ was confirmed by X-ray diffraction, as shown in FIG. 6.

### Example 4: Doping of LaNiO₃ with Cu

The LaNiO₃ matrix can be doped with Cu to alter its electrical properties. This was done by exchanging some pulses of nickel precursor in the method of Example 1 with pulses of Cu(acac)₂. Crystalline films were obtained as deposited on HF-etched silicon substrates. No special preparation of the silicon substrates was required. For copper substitution, Cu(acac)₂ was held at 140° C. throughout the deposition. The copper precursor does not exhibit a trimeric structure upon sublimation, and the crystallinity of the films decreased as the amount of the copper in the films was increased. It was found that the electrical conductivity of the films could be tuned smoothly from 3×10⁻⁴ Ωcm to approximately 100 Ωcm, covering more than 6 orders of magnitude (see FIG. 7). The samples in this composition series exhibited completely different resistivity variation upon changes in temperature (see FIG. 8).

### Example 5: Deposition of LaNiO₃

Thin film depositions of LaNiO₃(LNO) were carried out in an F-120 Sat ALD reactor (ASM Microchemistry). The deposition temperature was 225° C. with an operating pressure of 2.4 mbar, maintained by a 300 cm³ min⁻¹ primary flow rate of N₂.

Nitrogen was supplied from gas cylinders (Praxair, 99.999%) and run through a Mykrolis purifier for removal of any oxygen or water contamination.

La(thd)₃ (Volatech, 99%) and Ni(acac)₂ (Sigma Aldrich, 97%) were used as cation precursors. Both precursors were supplied from open boats inside the reactor, and maintained at 185° C. throughout the deposition. Ni(acac)₂ was re-sublimated at 175° C. for purification prior to use in the reactor. The cation precursors were pulsed into the reaction chamber by means of inert gas valves. 03 was used as the oxygen source, made from O₂ (Praxair, 99.5%) using an AC-2505 (In USA) ozone generator supplying 15 wt. % O₃ in O₂. Pulse durations were 2, 2 and 4 s for La(thd)₃, Ni(acac)₂ and O₃, respectively. Purge durations were 2 s after cation precursor pulses, and 3 s after the ozone pulses. Self-limiting behavior for the employed pulse- and purge scheme was confirmed.

Thin films were deposited on 1×1 cm² Si for routine characterization of thickness and 3×3 cm² Si for analysis of conformality and cation stoichiometry. Selected compositions were deposited on LaAlO₃ (LAO) (100) (Crystal GmbH), (110) and (111) (MTI Corp.) and SrTiO₃ (STO) (100) (Crystal GmbH), (110) and (111) (MTI Corp.) single crystals for facilitation of epitaxial growth.

Room-temperature resistivity measurements were carried out using a 4-point probe and a Keithley model 2400 SourceMeter. The sheet resistivity was recorded by measuring resistance in 10 points from 1 to 10 μA. Variable temperature resistivity measurements were performed on a Model 4000 physical property measurement system (PPMS, Quantum Design). The samples were mounted on a puck and contacted with gold wires on gold pads deposited by evaporation. Resistivity was collected in a 4-point setup, while the temperature was swept from 300 to 6 K.

4-point probe measurements (point distance 1 mm) at room temperature revealed metallic electrical resistivity. STO(100)∥LNO(100)_{pseudocubic(pc)} exhibited a resistivity of ˜100 μΩcm on average, with a lowest measured resistivity of 80 μΩcm. This is below the reported values for bulk LNO. For LA(100)_{pc}∥LNO(100)_{pc} the average resistivity measured was ˜300 μΩcm, which is slightly higher than bulk LNO.

To further investigate the electrical properties of the sample, a Hall analysis was carried out using a 4-point setup in which each corner of the 1×1 cm² sample was contacted to a probe. The film was perturbed by a 1.02 T magnet, which allowed for measurements of induced Hall currents and deduction of carrier densities.

The resistivity was estimated to be 138 μΩcm for STO (100)∥LNO(100)_{pc} at ambient temperature, which was slightly higher than measured by the 4-point probe. This is likely because the Hall-setup uses a much larger probe distance (10× longer), which is less tolerant to any grain boundaries that may exist in the film. It should still be noted that the resistivity is on par with that of bulk LNO (˜120μΩ cm).

The induced Hall voltage was measured to be ˜2 mV A⁻¹. Using the film conductivity, sample thickness, current and magnetic field, a Hall coefficient of 0.0549 mm³ C⁻¹ and a charge carrier density of ˜3.6×10²² cm⁻³ could be deduced. This is very close to the theoretical 3.4×10²² cm⁻³ carriers that would be present if each NiO₆-octahedron contributes with one carrier each. High carrier density is key for materials that are to be used as gates in oxide electronics.

The temperature dependent resistivity of the LNO films on STO was measured using a PPMS cooled by liquid He. The temperature was swept from room temperature to 6 K and the resistivity was collected for every 2 K. The results showing a decrease in resistivity as a function of temperature underpin that the films are metallic across the whole temperature range.

1. A method for the formation of a rare earth nickelate-containing film, or a doped variant thereof, on a substrate by atomic layer deposition, said method comprising the following steps:
a) providing a substrate in a reaction chamber wherein said reaction chamber is arranged for gas-to-surface reactions;
b) depositing a rare earth nickelate, or doped variant thereof, on at least a portion of said substrate by means of a deposition cycle which comprises sequential pulsing of a rare earth precursor, an oxygen precursor, a nickel precursor and, optionally, one or more dopant precursors, through said reaction chamber whereby to cause each precursor to deposit on and/or react with at least one surface of said substrate; and
c) repeating step b), if desired, until the required film thickness is obtained;
wherein the deposition cycle in step b) comprises the following steps i) and ii) carried out sequentially:
i) sequential pulsing of said rare earth precursor and said oxygen precursor, repeated “A” times;
ii) sequential pulsing of said nickel precursor and said oxygen precursor, repeated “B” times, in which at least one pulse of said nickel precursor is optionally substituted by a pulse of a dopant precursor;
wherein:
A is 5 or 10;
B is 2 or 4; and
the ratio of A:B is 2.5:1;
and further wherein the nickel precursor is [Ni(acac)₂]₃.

2. A method as claimed in claim 1, wherein said rare earth precursor comprises La, Pr, Nd, Sm, Eu, Gd, Tb, Dy, Ho, Er, Tm, Yb or Lu, preferably La, Pr, Nd, Sm, Eu, Gd, or Tb, more preferably La, Pr, Nd, or Sm.

3. A method as claimed in claim 2, wherein said rare earth precursor is RE(thd)₃, wherein RE=La, Pr, Nd, Sm, Eu, Gd, Tb, Dy, Ho, Er, Tm, Yb or Lu.

4. A method as claimed in claim 3, wherein said rare earth precursor is La(thd)₃.

5. A method as claimed in any one of the preceding claims, wherein said nickel precursor is formed by sublimation of Ni(acac)₂ prior to introduction into the reaction chamber.

6. A method as claimed in any one of the preceding claims, wherein at least one, but not all, of the pulses of said nickel precursor are replaced by a pulse of a copper precursor.

7. A method as claimed in claim 6, wherein the copper precursor is Cu(acac)₂.

8. A method as claimed in any one of the preceding claims, wherein the resulting rare earth nickelate-containing film, or doped variant thereof, is not subjected to any post-annealing treatment.

9. A method as claimed in any one of the preceding claims, wherein said oxygen precursor is H₂O, O₃, or a combination thereof, preferably O₃.

10. A method as claimed in any one of the preceding claims, wherein said substrate is Si, SiO₂, Si/SiO₂, Si/Pt, Pt, Ti, Al₂O₃, glass, LaAlO₃, MgO, SrLaAlO₄, SrTiO₃, KNbO₃, K(Nb,Ta)O₃, NdGaO₃, TbScO₃, or YAlO₃.

11. A method as claimed in any one of the preceding claims, wherein said method is performed at a temperature of less than 300° C., preferably less than 250° C.

12. A method for the formation of a rare earth nickelate-containing film, or a doped variant thereof, on a substrate by atomic layer deposition, said method comprising the following steps:
a) providing a substrate in a reaction chamber wherein said reaction chamber is arranged for gas-to-surface reactions;
b) depositing a rare earth nickelate, or doped variant thereof, on at least a portion of said substrate by means of a deposition cycle which comprises sequential pulsing of a rare earth precursor, an oxygen precursor, a nickel precursor and, optionally, one or more dopant precursors, through said reaction chamber whereby to cause each precursor to deposit on and/or react with at least one surface of said substrate; and
c) repeating step b), if desired, until the required film thickness is obtained;
wherein the nickel precursor is [Ni(acac)₂]₃; and
wherein the rare earth precursor is other than La(thd)₃.

13. A method as claimed in claim 12, wherein the rare earth precursor does not contain lanthanum.

14. A method as claimed in claim 12, wherein the rare earth precursor comprises Pr, Nd, Sm, Eu, Gd, Tb, Dy, Ho, Er, Tm, Yb, or Lu, or any combination thereof.

15. A method as claimed in claim 12, wherein the rare earth precursor comprises lanthanum in combination with a different rare earth element.

16. A method for the formation of a doped rare earth nickelate-containing film on a substrate by atomic layer deposition, said method comprising the following steps:
a) providing a substrate in a reaction chamber wherein said reaction chamber is arranged for gas-to-surface reactions;
b) depositing a doped rare earth nickelate on at least a portion of said substrate by means of a deposition cycle which comprises sequential pulsing of a rare earth precursor, an oxygen precursor, a nickel precursor, and one or more dopant precursors, through said reaction chamber whereby to cause each precursor to deposit on and/or react with at least one surface of said substrate; and
c) repeating step b), if desired, until the required film thickness is obtained;
wherein the nickel precursor is [Ni(acac)₂]₃.

17. A substrate carrying a rare earth nickelate-containing film, or doped variant thereof, obtained or obtainable by a method as claimed in any one of claims 1 to 16.

18. A substrate carrying a doped variant of a rare earth nickelate-containing film as claimed in claim 17, wherein said film comprises copper.

19. A substrate carrying a rare earth nickelate-containing film, or doped variant thereof, as claimed in claim 17 or claim 18, wherein said film has a thickness in the range of 1.5 to 200 nm.

20. A substrate carrying a rare-earth nickelate-containing film, or doped variant thereof, as claimed in any one of claims 17 to 19, wherein said film has a resistivity in the range of 1×10⁻⁵ to 100 Ωcm, preferably 3×10⁻⁴ to 100 Ωcm, e.g. 3×10⁻⁴ to 2×10⁻³ Ωcm.

21. A rare-earth nickelate-containing film as characterised by one or more of the following: (i) an X-ray diffraction pattern according to that labelled 5:2 in FIG. 2; (ii) an X-ray diffraction pattern according to that labelled 10:4 in FIG. 2; (iii) an X-ray diffraction pattern according to that labelled 5:2 in FIG. 3; or (iv) an X-ray diffraction pattern according to that labelled 10:4 in FIG. 3.

22. Use of a substrate carrying a rare-earth nickelate-containing film, or doped variant thereof, as claimed in any one of claims 17 to 21 in the production of a battery, a supercapacitor, a surface acoustic wave device, a ferroelectric random-access memory, a transducer, an ion conductor, an optoelectronic device, a Mott transistor, an actuator, a sensor, a magnetoelectric device, an electrode, or a catalytic surface.
